(19) United States
(12) Patent Application Publication
(10) Pub. No.: US 2011/0031108 A1
(43) Pub. Date: Feb. 10, 2011

(54) SPUTTERING DEPOSITION METHOD AND APPARATUS

(75) Inventors: GA-LANE CHEN, Santa Clara, CA (US); CHAO-TSANG WEI, Tu-Cheng (TW); CHING-CHOU CHANG, Tu-Cheng (TW); SHIH-CHE CHIEN, Tu-Cheng (TW); WEI-CHENG LING, Tu-Cheng (TW); CHUNG-PEI WANG, Tu-Cheng (TW); CHIA-YING WU, Tu-Cheng (TW); CHIEN-HAO HUANG, Tu-Cheng (TW); HSIN-CHIN HUNG, Tu-Cheng (TW); MING-YANG LIAO, Tu-Cheng (TW); TAI-SHENG TSAI, Tu-Cheng (TW); SHAO-KAI PEI, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/844,804

(22) Filed: Jul. 27, 2010

(30) Foreign Application Priority Data
Aug. 4, 2009 (CN) 200910305158.9

(51) Int. Cl. C23C 14/34

(52) U.S. Cl. 204/192.12; 204/298.07

(57) ABSTRACT

A sputtering deposition method is utilized by a sputtering deposition apparatus including a first chamber, a second chamber, a first carrier, and a second carrier. Some first substrates are positioned in the first carriers in the first chamber for heating. The first carriers in the first chamber and the second carriers in the second chamber are exchanged. The first substrates in the second chamber are sputtered. The second carriers in the first chamber and the first carriers in the second chamber are exchanged. The first substrates in the first chamber are taken out.

### BACKGROUND

1. Technical Field

The disclosure generally relates to film deposition method, and particularly to a sputtering deposition method and apparatus.

2. Description of Related Art

Generally, to deposit a thin film on a substrate by sputtering of a target, the following steps are required. First, the substrate and the target are placed in a chamber. Then, the chamber is vacuumized. A sputtering gas is introduced into the vacuumized chamber and ionized and accelerated to bombard the target. The target is caused to sputter to deposit the thin film on the substrate by the bombardment of the ionized sputtering gas. After the sputtering deposition, the substrate is taken out of the chamber. As such, the chamber needs to be vacuumized prior to each instance of sputtering deposition, reducing convenience and efficiency while increasing costs. In addition, the target may be oxidized when the chamber device is opened, reducing purity of the target.

What is needed, therefore, is a sputtering deposition method which can overcome the limitations described.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout various views.

FIGS. 1 and 3-5 are schematic views of a sputtering deposition apparatus in different operating states respectively, according to one embodiment.

FIG. 2 is a block diagram of a sputtering deposition method in accordance with one embodiment.

### DETAILED DESCRIPTION

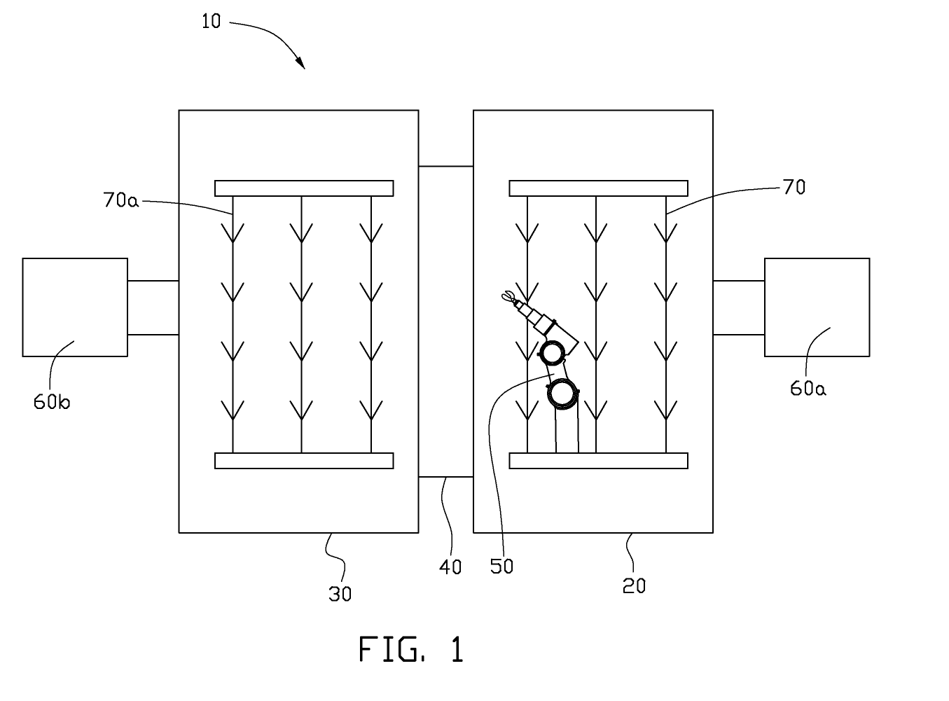

Referring to FIG. 1, one embodiment of a sputtering deposition apparatus 10 includes a first chamber 20, a second chamber 30, a separating device 40, an exchanging device 50, and two air pumps 60a, 60b.

A plurality of first carriers 70 is received in the first chamber 20. The first carriers 70 are configured for holding a plurality of first substrates 80. A plurality of second carriers 70a is received in the second chamber 30. The second carriers 70a are configured for holding a plurality of second substrates 90. The separating device 40 is disposed between the first chamber 20 and the second chamber 30 and constructed to open or hermetically close the first chamber 20 and the second chamber 30. As such, when the separating device 40 is opened, the first chamber 20 communicates with the second chamber 30. When the separating device 40 is closed, the first chamber 20 and the second chamber 30 are hermetically separated from each other. In this embodiment, the exchanging device 50 is disposed in the first chamber 20. The exchanging device 50 is configured for exchanging the carriers 70, 70a between the first chamber 20 and the second chamber 30. The air pumps 60a, 60b are connected to the first chamber 20 and the second chamber 30 correspondingly. The first chamber 20 and the second chamber 30 are vacuumized by the air pumps 60a, 60b. Here, the separating device 40 is a valve. The exchanging device 50 is a robot arm.

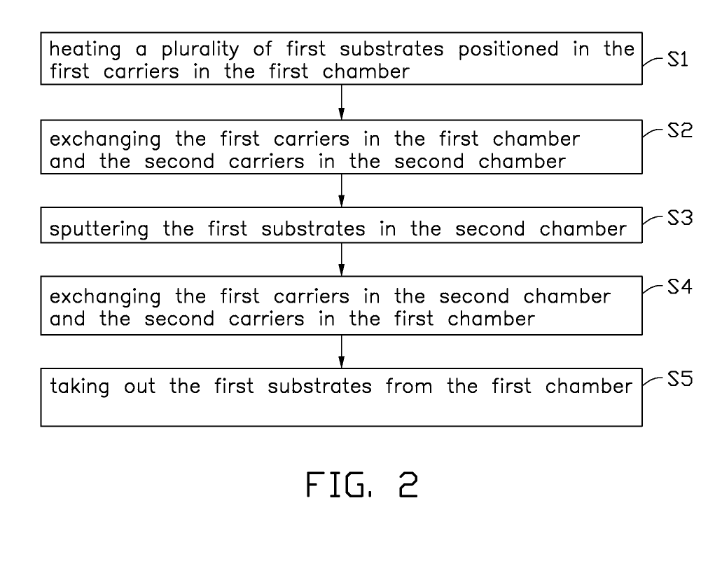

Referring to FIG. 2, one embodiment of a sputtering deposition method is provided.

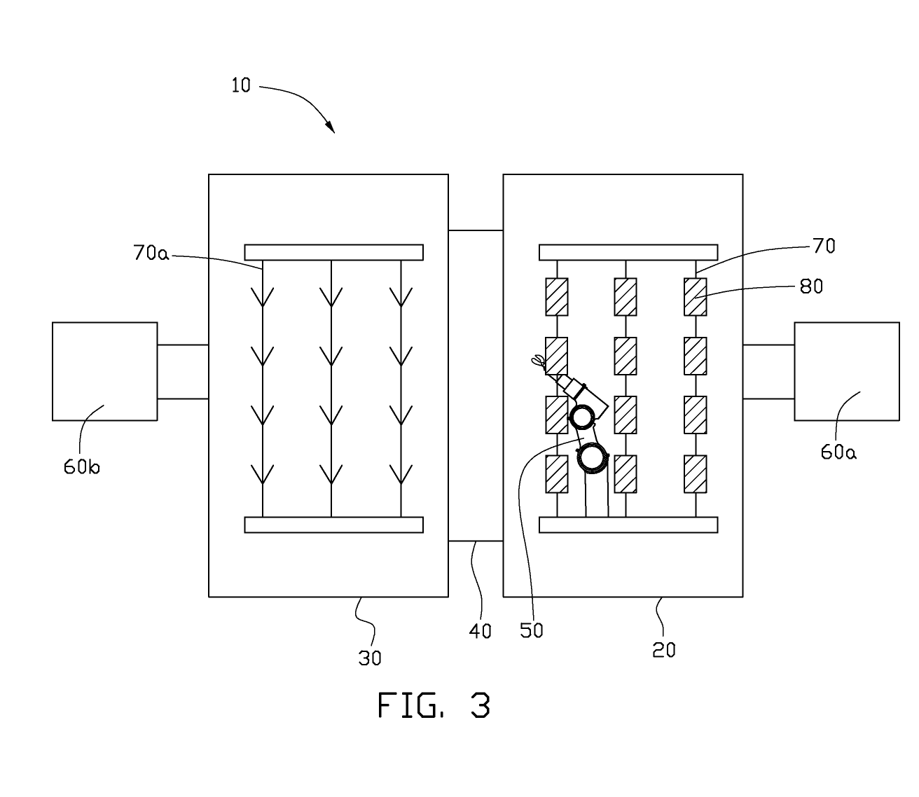

Also referring to FIG. 3, in Step S1, a plurality of first substrates is positioned in the first carriers in the first chamber for heating. The separating device 40 is closed, and the first chamber 20 and the second chamber 30 are hermetically separated from each other. The first substrates 80 are positioned in the first carriers 70 in the first chamber 20. The first chamber 20 and the second chamber 30 are vacuumized by the air pumps 60a, 60b. The first substrates 80 are heated.

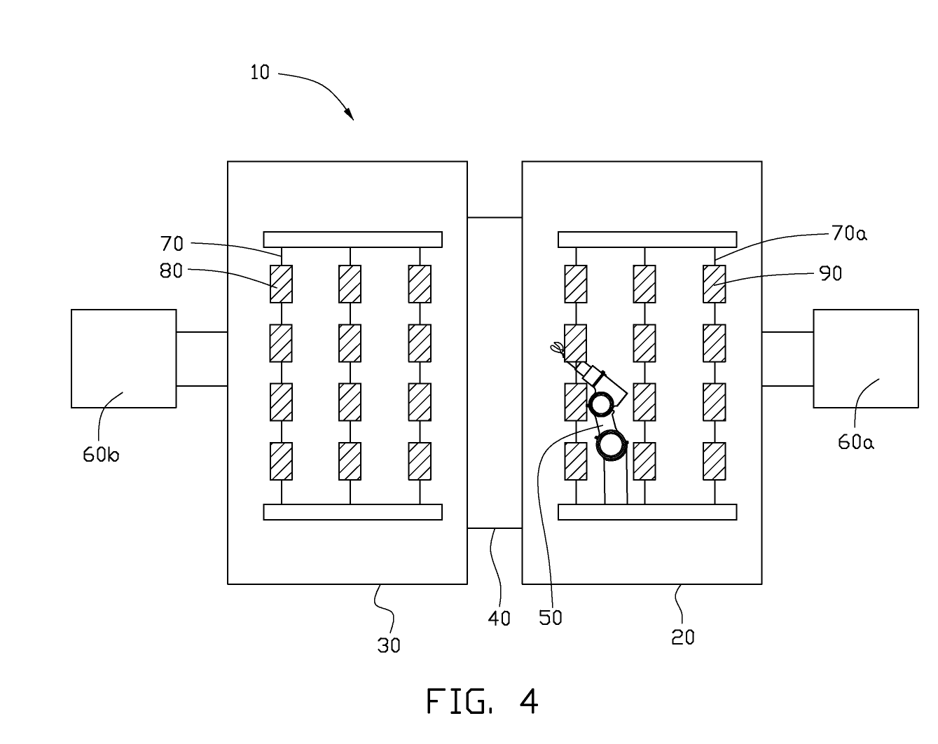

Referring to FIG. 4, in Step S2, the first carriers in the first chamber and the second carriers in the second chamber are exchanged. The separating device 40 is opened, and the first chamber 20 communicates with the second chamber 30. After heating the first substrates 80, the exchanging device 50 exchanges the first carriers 70 in the first chamber 20 with the second carriers 70a in the second chamber 30. Then, the separating device 40 is closed. A plurality of second substrates 90 is positioned in the second carriers 70a in the first chamber 20. The first chamber 20 is vacuumized by the air pumps 60a. The second substrates 90 are heated.

In Step S3, the first substrates in the second chamber are sputtered. After the first carriers 70 in the first chamber 20 are exchanged with the second carriers 70a in the second chamber 30, the separating device 40 is closed, and the first substrates 80 in the second chamber 30 are sputtered. The second substrates 90 in the first chamber 20 are heated at the same time.

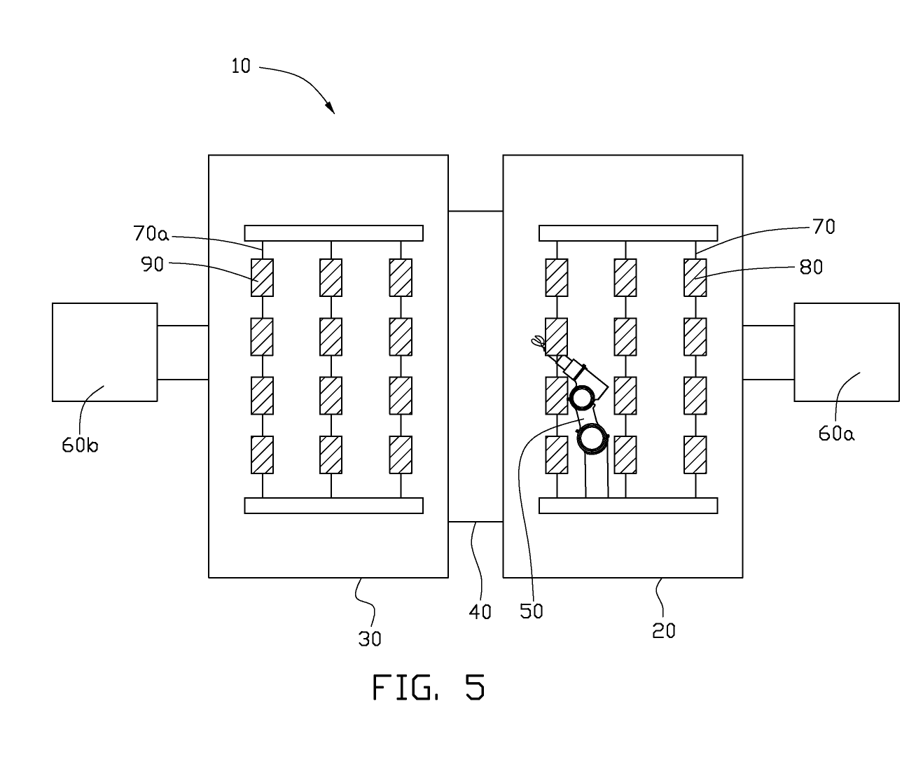

Referring to FIG. 5, in Step S4, the second carriers in the first chamber and the first carriers in the second chamber are exchanged. The separating device 40 is opened, and the first chamber 20 communicates with the second chamber 30. After sputtering the first substrates 80, the exchanging device 50 exchanges the second carriers 70a in the first chamber 20 with the first carriers 70 in the second chamber 30. Then, the separating device 40 is closed.

In step S5, the first substrates in the first chamber are taken out. After the separating device 40 is closed, the first substrates 80 in the first chamber 20 are taken out. The second substrates 90 are sputtered in the second chamber 30 at the same time.

It should be noted that the two chambers 20, 30 can host different processes at the same time. The second chamber 30 does not need to be vacuumized prior to each instance of sputtering deposition. Thus, the method reduces working time and increases efficiency.

It is to be understood, however, that even though numerous characteristics and advantages of various embodiments have been set forth in the foregoing description, together with details of the structures and functions of the embodiments, the disclosure is illustrative only; and that changes may be made in detail, especially in matters of arrangement of parts within the principles of the invention to the full extent indicated by the broad general meaning of the terms in which the appended claims are expressed.

What is claimed is:

1. A sputtering deposition method, utilized by a sputtering deposition apparatus comprising a first chamber, a second chamber, a first carrier and a second carrier, the method comprising:
heating a first substrate positioned in the first carrier in the first chamber;
exchanging the first carrier in the first chamber and the second carrier in the second chamber;
sputtering the first substrate in the second chamber;
exchanging the second carrier in the first chamber and the first carrier in the second chamber; and
taking out the first substrates from the first chamber.

2. The method as claimed in claim 1, wherein the sputtering deposition apparatus comprises a separating device positioned between the first chamber and the second chamber and constructed to open or hermetically close the first chamber and second chamber.

3. The method as claimed in claim 2, wherein before the first substrate is heated, the separating device is closed, the first chamber and the second chamber are hermetically separated from each other.

4. The method as claimed in claim 2, wherein before the first and second carriers are exchanged, the separating device is opened, the first chamber communicates with the second chamber.

5. The method as claimed in claim 2, wherein before the first substrate is sputtered, the separating device is closed, the first chamber and the second chamber are hermetically separated from each other.

6. The method as claimed in claim 1, wherein the sputtering deposition apparatus comprises two air pumps connected to the first chamber and the second chamber, the first chamber and the second chamber are vacuumized by the air pumps.

7. The method as claimed in claim 1, wherein after the first carrier and the second carrier are exchanged, a second substrate is positioned in the second carrier in the first chamber.

8. The method as claimed in claim 7, wherein when the first substrate in the second chamber is sputtered, the second substrate in the first chamber is heated.

9. The method as claimed in claim 7, wherein when the first substrate in the first chamber is taken out, the second substrate in the second chamber is sputtered.

10. A sputtering deposition apparatus, comprising:
a first chamber;
a second chamber communicated with the first chamber;
a plurality of first carriers received in the first chamber;
a plurality of second carriers received in the second chamber;
a separating device positioned between the first chamber and the second chamber and constructed to open or hermetically close the first chamber and second chamber; and
an exchanging device configured for exchanging the first and second carriers in the first chamber and the second chamber;
two air pumps connected to the first chamber and the second chamber, the air pumps being configured to vacuumize the first chamber and the second chamber.

11. The sputtering deposition apparatus as claimed in claim 10, wherein the separating device is a valve.

12. The sputtering deposition apparatus as claimed in claim 10, wherein the exchanging device is a robot arm.

13. A sputtering deposition apparatus, comprising:
a first chamber;
a second chamber;
a separating device connected the first chamber to the second chamber and configured to be opened to communicate the first chamber to the second chamber, and to be closed to separate the first chamber from the second chamber;
a plurality of first carriers capable of being moved from one of the first and second chambers into another one of the first and second chambers; and
a plurality of second carriers capable of being moved from one of the first and second chambers into another one of the first and second chambers.

14. The sputtering deposition apparatus as claimed in claim 13, further comprising an exchanging device configured to move the first carriers from one of the first and second chambers into another one of the first and second chambers, and to move the second carriers from one of the first and second chambers into another one of the first and second chambers.

15. The sputtering deposition apparatus as claimed in claim 13, further comprising two air pumps, each of the two air pumps being connected to a corresponding one of the first chamber and the second chamber.

16. The sputtering deposition apparatus as claimed in claim 13, wherein the separating device is a valve.

17. The sputtering deposition apparatus as claimed in claim 14, wherein the exchanging device is a robot arm.
